(19) United States
(12) Patent Application Publication
(10) Pub. No.: US 2004/0196102 A1
(43) Pub. Date: Oct. 7, 2004

(54) Bias current control in transistors

(76) Inventor: Hans Eriksson, Jarfalla (SE)

Correspondence Address: JENKENS & GILCHRIST, PC, 1445 ROSS AVENUE, SUITE 3200, DALLAS, TX, 75202, US

(21) Appl. No.: 10/479,480

(22) PCT Filed: May 23, 2002
(86) PCT No.: PCT/SE02/00983

(30) Foreign Application Priority Data
Jun. 1, 2001 (SE) 0101961.1

(51) Int. Cl. H03G 3/10

(52) U.S. Cl. 330/285

(57) ABSTRACT

The invention relates to an arrangement for and a method of measuring and adjusting the bias current (Ib) in transistors (28) used in class AB or class B type amplifiers (30), characterised by the steps of repetitively measuring (110) the bias current (Ib) during operation without interrupting the normal transmission for the power amplifier (30), and repetitively adjusting (200) the bias current (Ib) during operation thus keeping it stable over time and temperature.

### TECHNICAL FIELD OF THE INVENTION

The invention relates to a method of and an arrangement for measuring and adjusting the bias current during operation in transistors used in class AB or class B type amplifiers.

### DESCRIPTION OF RELATED ART

With bias current is meant a pre-set DC current through a transistor. The current in a transistor used in a class AB or class B type of amplifier is in addition to the bias current also dependent on the input signal, i.e. the input signal voltage, to the transistor. Thus, the bias current for a transistor in a class AB or class B amplifier is the current through the transistor when no input signal voltage is present. The normal way to set the bias current for a transistor is to provide, when no input signal voltage is present, a pre-set bias voltage using an adjustable voltage connected to the input of the transistor and adjusted to give the wanted bias current through the transistor. Normally, the pre-set bias voltage in power amplifier transistors and driver transistors is set once and for all at the factory and is not normally altered during the life span of the device comprising the transistor, e.g. a transmitter used in a base station. Further, some additional means to adjust this pre-set bias voltage with the change in transistor temperature so the bias current is kept approximately stable even when the transistor temperature changes may be arranged.

Modern modulation methods like EDGE involve a large degree of AM modulation, and in order to be able to transmit this kind of signals a transmitter has to have a linear relation between input and output signal in order to not destroy the amplitude information. Power amplifier transistors and driver transistors have best linearity at a specific bias current. Linearity is usually achieved by “backing off” the signal in a power amplifier, for example by letting a power transistor capable of delivering 100 W output power to deliver only up to 50 W of output power. This means that a transistor with twice the maximum output power needed has to be used to get enough linearity. This is called a back off of 3 dB (twice the power). There is also a drop in efficiency usually proportional to the square root of power ratio. When using a power transistor capable of delivering 100 W output power at only 50 W output power the efficiency drops the square root of 0.5, i.e. to 0.7, i.e. to 70% of the efficiency at the maximum output power. 100 W. Realistic figures for the efficiency are 50% efficiency at full power, 100 W, and 35% at a power back off down to 50 W. Lower efficiency means that bigger and heavier cooling fins are needed at the power amplifier which emits more heat to dissipate and that a bigger and heavier power supply unit having bigger maximum output power must be used. To obtain 50 W effective output power in the example above, the power supply unit maximum output power must be increased from 100 W to 143 W (100 W×50%=143 W×35%). Consequently, maintaining the linearity for the power transistor and thereby minimising the need for back off has a high economical impact on the whole base station.

The conventional method of measuring and adjusting the bias current in transmitters as described above has the following disadvantages: In the first place, the bias current in the transistor will change over time due to internal changes, i.e. ageing, in the transistor. Secondly, it is impossible to find out and measure the true value of the transistor temperature. Usually the temperature is measured close to the transistor heat sink. The true temperature of the transistor is in this case higher than the measured temperature, but how much higher depends on how high the current going through the transistor is. Usually a temperature increase corresponding to somewhere between the minimum current and the maximum current is added to the measured value. Thirdly, the pre-set bias voltage in power amplifier transistors and driver transistors is difficult to alter during the life span of the device comprising the transistor. Fourthly, power amplifier transistors and driver transistors have best linearity at a specific bias current which is difficult to maintain due to the changes in the true transistor temperature and ageing of the transistor. Fifthly, it is not possible to measure and adjust the bias current during operation.

### SUMMARY OF THE INVENTION

The object of the invention is to bring about a method and an arrangement relating to measuring and adjusting the bias current in transistors used in class AB or class B type amplifiers during operation.

This is achieved by the use of a method of and an arrangement for measuring and adjusting the bias current in transistors used in class AB or class B type amplifiers during operation comprising the step of repetitively measuring the bias current during operation without interrupting the normal transmission for the power amplifier and the step of repetitively adjusting the bias current during operation thus keeping it stable over time and temperature.

The method and arrangement according to the invention has the following advantages: The repetitive measurement of the bias current makes it possible to have a high degree of control over the bias current value. Further, the bias current may be kept under software control, which makes it possible to change or check the bias current without any change in hardware. Moreover, with the better control of the bias current, it is possible to allow the power amplifier transistors to work close to optimal linearity. Further, it is not necessary to try to find out and measure the true value of the transistor temperature. It is also possible to measure and adjust the bias current during operation.

### BRIEF DESCRIPTION OF THE DRAWINGS

The invention will be described in more detail below with reference to the appended drawings, wherein:

FIG. 1 shows a block diagram of a prior-art arrangement,

FIG. 2 shows a schematic block diagram of the arrangement according to the invention,

FIG. 3 shows some steps of the method according to the invention, and

FIG. 4 shows schematically the current in a transistor over time.

### DETAILED DESCRIPTION OF EMBODIMENTS

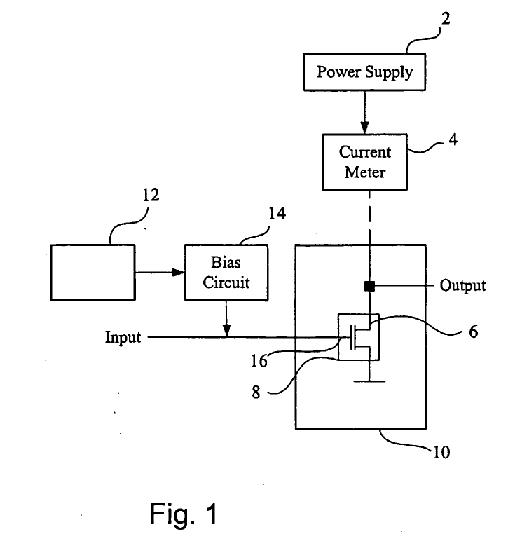

On the drawings, FIG. 1 shows a block diagram of a prior-art arrangement. The prior art arrangement for measuring and adjusting the bias current in transistors used in class AB or class B type amplifiers comprises a power supply 2, a current meter 4 connected to the current supply 2 where the current meter 4 is further connected via electronic circuits (not shown) to the drain 6 in a transistor 8 used in a class AB or class B type power amplifier 10, an adjustable voltage 12, and a bias circuit 14 connected to the adjustable voltage 12 where the bias circuit 14 is further connected to the gate 16 in the transistor 8.

The method of measuring and adjusting the bias current in transistors used in class AB or class B type amplifiers according to the prior-art arrangement comprises the step of measuring, when no input signal voltage is present, the bias current for the transistor 8 while pre-setting the bias voltage using the adjustable voltage 12 connected via the bias circuit 14 to the gate 16 in the transistor 8 to get a wanted bias current through the transistor 8. Normally, the pre-set bias voltage in power amplifier transistors and driver transistors is set once and for all at the factory and is not normally altered during the life span of the device comprising the transistor, e.g. a transmitter used in a base station.

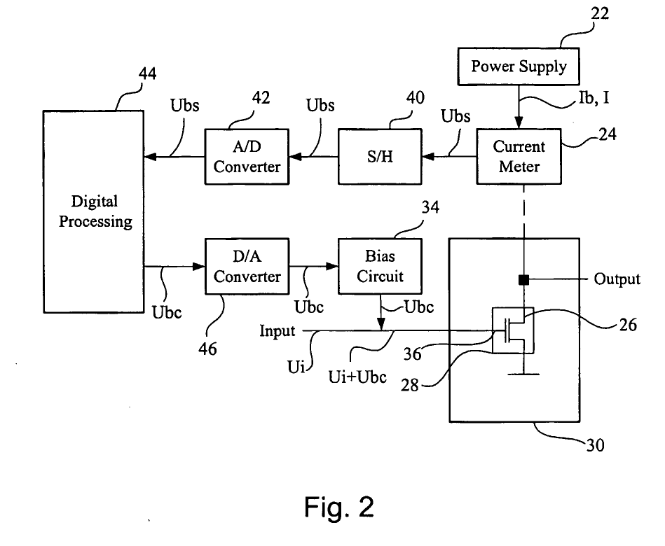

FIG. 2 shows a schematic block diagram of the arrangement according to the invention. The arrangement according to the invention for measuring and adjusting the bias current in transistors used in class AB or class B type amplifiers during operation comprises a power supply 22, a current meter 24 connected to the power supply 22 where the current meter 24 is further connected via electronic circuits (not shown) to the drain 26 in a transistor 28 used in a class AB or class B type power amplifier 30, a sample and hold circuit 40 connected to the current meter 24, an A/D converter 42 connected to the sample and hold circuit 40, a digital processing device 44 connected to the A/D converter 42, a D/A converter 46 connected to the digital processing device 44, and a bias circuit 34 connected to the D/A converter 46 where the bias circuit 34 is further connected to the gate 36 in the transistor 28.

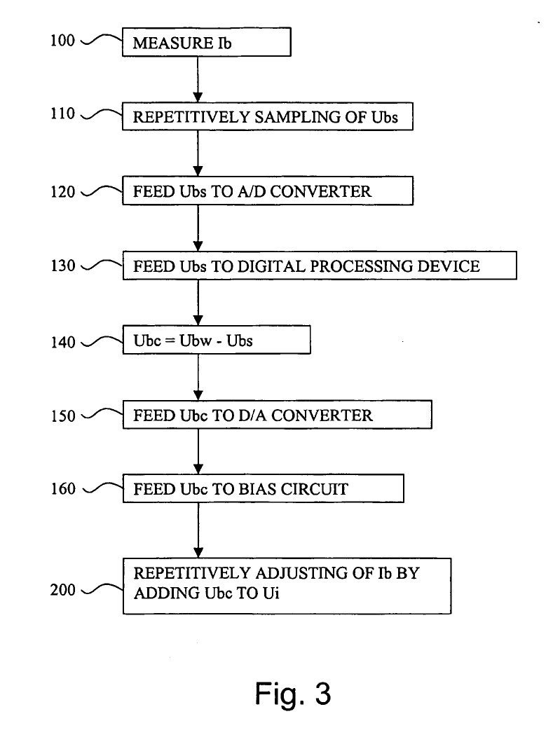

FIG. 3 shows some steps of the method according to the invention. The method of measuring and adjusting the bias current Ib in transistors 28 used in class AB or class B type amplifiers 30 during operation according to the invention comprises the steps of repetitively measuring 110 the bias current Ib without interrupting the normal transmission for the power amplifier 30, and repetitively adjusting 200 the bias current Ib thus keeping it stable over time and temperature. The basic idea is to repetitively take short samples 110 representing the current Ib delivered by the power supply 22 when the input signal to the power amplifier 30, i.e. to the transistor 28, is absent. The current Ib drawn from the power supply 22 to the output termination, i.e. drain 26, of the transistor 28 when the input signal Ui to the transistor 28 is absent is the bias current Ib. Firstly, the bias current Ib is measured 100 with an ordinary current meter 24. The current meter 24 is connected to a sample and hold circuit 40. The sample and hold circuit 40 samples 110 a voltage Ubs proportional to the bias current Ib. The sampled value of the voltage signal Ubs is then fed 120 to an A/D converter 42, if the sampled value as in this embodiment is to be used in a digital bias correction circuit 44. From the A/D converter 42, the sampled bias voltage value Ubs is fed 130 to a digital processing device 44 where it is compared 140 to the wanted bias voltage value Ubw. Any difference between the sampled bias voltage value Ubs and the wanted bias voltage value Ubw will result in a correction bias voltage value Ubc. This correction bias voltage value Ubc is fed 150 to a D/A converter 46. From the D/A converter 46, the correction bias voltage value Ubc is fed 160 to a bias circuit 34 and therefrom the correction bias voltage value Ubc is added 200 to the gate 36 of the transistor 28 and thus to the input signal voltage Ui entering the transistor through the gate 36. A normal wanted bias current value Tbw for a power transistor with maximum output power of 100 W could be around 1A. The relationship between the wanted bias current value Ibw and the wanted bias voltage value Ubw is set arbitrary. One way to set the relationship is to use a linear relationship between Ubw and Ibw so that Ubw=k×Ibw where the factor k is chosen so that the voltage is adapted to the chosen components A/D converter, D/A converter, sample and hold circuit etc.

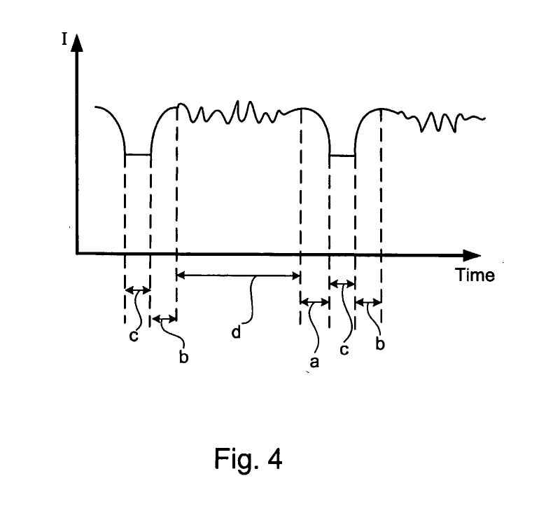

FIG. 4 shows schematically the current I in a transistor over time. When the signals to be sampled are ordinary GMSK and EDGE type of signals with power ramping a,b, the current measurements c can be taken between the bursts d, after the output power has been ramped down a and before it is ramp up b again. This is preferred because it does not interfere with the ordinary transmission d. At signals without any power ramping any short brake in transmission can be used for current measurement, e.g. empty bursts under low traffic periods. In this case it can not be guaranteed that enough of samples will be taken. The time to take a sample of the current is in the order of a few μs with a modern sample and hold detector. If the bursts come every 0,5 ms, around 2000 samples could be taken every second. The drift of the bias current with time is usually very slow so the number of samples needed for compensation is very limited, such as one per day or one per week. If the method is also used for temperature compensation the number of samples taken must be dimensioned according to the temperature stability of the power amplifier.

1. A method of measuring and adjusting the bias current in transistors (28) used in class AB or class B type amplifiers (30) comprising the steps of:
repetitively measuring (110) the bias current (Ib) during operation without interrupting the normal transmission for the power amplifier (30), and
repetitively adjusting (200) the bias current (Ib) during operation thus keeping it stable over time and temperature, wherein the method is characterised in that, the step of repetitively adjusting the bias current (Ib) during operation thus keeping it stable over time and temperature comprises the step of: adding (200) the correction bias voltage value (Ubc) to the gate (36) of the transistor (28) and thus to the input signal voltage (Ui) entering the transistor (28) through the gate (36).

2. A method of measuring and adjusting the bias current in transistors (28) used in class AB or class B type amplifiers (30) according to claim 1, characterised in, that the step of repetitively measuring the bias current (Ib) during operation without interrupting the normal transmission for the power amplifier (30) comprises the step of: repetitively taking short samples (110) representing the current (Ib) delivered by the power supply (22) when the input signal (Ui) to the power amplifier (30), i.e. to the transistor (28), is absent.

3. A method of measuring and adjusting the bias current in transistors (28) used in class AB or class B type amplifiers (30) according to claim 1, characterised in, that the step of repetitively measuring the bias current (Ib) during operation without interrupting the normal transmission for the power amplifier (30) comprises the steps of: measuring (100) the bias current (Ib) with an ordinary current meter (24) and sampling (110) a voltage (Ubs) proportional to the bias current (Ib).

4. A method of measuring and adjusting the bias current in transistors (28) used in class AB or class B type amplifiers (30) according to claim 1, characterised in, that the step of repetitively adjusting the bias current (Ib) during operation thus keeping it stable over time and temperature comprises the steps of: comparing (140) a sampled bias voltage value (Ubs) to the wanted bias voltage value (Ubw), any difference between the sampled bias voltage value (Ubs) and the wanted bias voltage value (Ubw) resulting in a correction bias voltage value (Ubc), and adding (200) the correction bias voltage value (Ubc) to the gate (36) of the transistor (28) and thus to the input signal voltage (Ui) entering the transistor (28) through the gate (36).

5. A method of measuring and adjusting the bias current in transistors (28) used in class AB or class B type amplifiers (30) according to any one of claims 2, 3 or 4, characterised in, that when the signals to be sampled are ordinary GMSK and EDGE type of signals with power ramping (a,b), current measurements (c) can be taken between bursts (d), after the output power has been ramped down (a) and before it is ramp up (b) again as it does not interfere with the ordinary transmission (d).

6. An arrangement for measuring and adjusting the bias current in transistors (28) used in class AB or class B type amplifiers (30), wherein the arrangement comprises means (24) for repetitively measuring the bias current (Ib) during operation without interrupting the normal transmission for the power amplifier (30), and means (34) for repetitively adjusting the bias current (Ib) during operation thus keeping it stable over time and temperature, wherein the arrangement is characterised in that, the means for repetitively adjusting the bias current (Ib) during operation thus keeping it stable over time and temperature comprises means (34) for adding (200) the correction bias voltage value (Ubc) to the gate (36) of the transistor (28) and thus to the input signal voltage (Ui) entering the transistor (28) through the gate (36).

7. An arrangement for measuring and adjusting the bias current in transistors (28) used in class AB or class B type amplifiers (30) according to claim 6, characterised in, that the means for repetitively measuring the bias current (Ib) during operation without interrupting the normal transmission for the power amplifier (30) comprises means (24, 40) for repetitively taking short samples (110) representing the current (Ib) delivered by the power supply (22) when the input signal (Ui) to the power amplifier (30), i.e. to the transistor (28), is absent.

8. An arrangement for measuring and adjusting the bias current in transistors (28) used in class AB or class B type amplifiers (30) according to claim 6, characterised in, that the means for repetitively measuring the bias current (Ib) during operation without interrupting the normal transmission for the power amplifier (30) comprises means (24) for measuring (100) the bias current (Ib) with an ordinary current meter (24) and means (40) for sampling (110) a voltage (Ubs) proportional to the bias current (Ib).

9. An arrangement for measuring and adjusting the bias current in transistors (28) used in class AB or class B type amplifiers (30) according to claim 6, characterised in, that the means for repetitively adjusting the bias current (Ib) during operation thus keeping it stable over time and temperature comprises means (44) for comparing (140) a sampled bias voltage value (Ubs) to the wanted bias voltage value (Ubw), any difference between the sampled bias voltage value (Ubs) and the wanted bias voltage value (Ubw) resulting in a correction bias voltage value (Ubc), and means (34) for adding (200) the correction bias voltage value (Ubc) to the gate (36) of the transistor (28) and thus to the input signal voltage (Ui) entering the transistor (28) through the gate (36).

10. An arrangement for measuring and adjusting the bias current in transistors (28) used in class AB or class B type amplifiers (30) according to any of claims 6 to 9, characterised in, that the arrangement comprises a power supply (22), a current meter (24) connected to the power supply (22) where the current meter (24) is further connected via electronic circuits (not shown) to the drain (26) in a transistor (28) used in a class AB or class B type power amplifier (30), a sample and hold circuit (40) connected to the current meter (24), an A/D converter (42) connected to the sample and hold circuit (40), a digital processing device (44) connected to the A/D converter (42), a D/A converter (46) connected to the digital processing device (44), and a bias circuit (34) connected to the D/A converter (46) where the bias circuit (34) is further connected to the gate (36) in the transistor (28).
